(19) United States
(12) Patent Application Publication
(10) Pub. No.: US 2025/0070721 A1
(43) Pub. Date: Feb. 27, 2025

(54) TRACKER CIRCUIT, TRACKER MODULE, AND VOLTAGE SUPPLY METHOD

(71) Applicant: Murata Manufacturing Co., Ltd., Nagaokakyo-shi (JP)

(72) Inventors: John HOVERSTEN, Waltham, MA (US); David PERREAULT, Waltham, MA (US); Yevgeniy TKACHENKO, Waltham, MA (US); Takeshi KOGURE, Nagaokakyo-shi (JP); Yuuki FUKUDA, Nagaokakyo-shi (JP); Toshiki MATSUI, Nagaokakyo-shi (JP)

(21) Appl. No.: 18/943,427

(22) Filed: Nov. 11, 2024

Related U.S. Application Data
(63) Continuation of application No. PCT/JP2023/015456, filed on Apr. 18, 2023.
(60) Provisional application No. 63/343,201, filed on May 18, 2022.

(51) Int. Cl. H03F 1/02; H03F 3/00; H03F 3/24

(52) U.S. Cl. CPC H03F 1/0227; H03F 3/005; H03F 3/245; H03F 2200/102; H03F 2200/105; H03F 2200/451

(57) ABSTRACT

In an exemplary aspect, a tracker circuit is provided that includes a first switch circuit configured to generate a plurality of discrete voltages, based on an input voltage, a second switch circuit configured to select at least a first voltage from the plurality of discrete voltages as a supply voltage, a filter circuit that is connected to the second switch circuit and is configured to filter the supply voltage and generate a filtered supply voltage that is provided to an amplifier via a voltage supply path between the filter circuit and the amplifier, and a third switch circuit including a capacitor and a switch that are connected in series between a ground and the voltage supply path.

### CROSS REFERENCE TO RELATED APPLICATIONS

This application is a continuation of International Application No. PCT/JP2023/015456, filed Apr. 18, 2023, which claims priority to U.S. Provisional Application No. 63/343,201, filed May 18, 2022, the entire contents of each of which are hereby incorporated by reference in their entireties.

### TECHNICAL FIELD

The present disclosure relates to a tracker circuit, a tracker module, and a voltage supply method.

### BACKGROUND

In recent years, power-added efficiency (PAE) has been improved through the application of an envelope tracking (ET) mode to power amplifier (PA) circuits. U.S. Pat. No. 9,755,672, (the “'672 patent”) discloses technology related to a digital ET mode, multiple discrete voltages are supplied.

However, with the existing technology described in the 672 patent, multiple discrete voltages supplied to an amplifier can be degraded.

### SUMMARY

In view of the foregoing, the exemplary aspects of the present disclosure provide a tracker circuit, a tracker module, and a voltage supply method that can suppress the degradation of multiple discrete voltages supplied to an amplifier.

In an exemplary aspect, a tracker circuit is provided that includes a first switch circuit configured to generate a plurality of discrete voltages, based on an input voltage, a second switch circuit configured to select at least a first voltage from the plurality of discrete voltages as a supply voltage, a filter circuit that is connected to the second switch circuit and is configured to filter the supply voltage and generate a filtered supply voltage that is provided to an amplifier via a voltage supply path between the filter circuit and the amplifier, and a third switch circuit including a capacitor and a switch that are connected in series between a ground and the voltage supply path.

In another exemplary aspect, a tracker module is provided that includes a module laminate having a first main surface and a second main surface that face each other, an external connection terminal provided in or on the module laminate, a first switch circuit that is arranged in or on the module laminate and is configured to generate, based on an input voltage, a plurality of discrete voltages, a second switch circuit that is arranged in or on the module laminate and is configured to select at least a first voltage from the plurality of discrete voltages as a supply voltage, a filter circuit that is arranged in or on the module laminate and is connected to the second switch circuit and is configured to filter the supply voltage and generate a filtered supply voltage that is provided to the external connection terminal via a voltage supply path, and a third switch circuit that is arranged in or on the module laminate and includes a capacitor and a switch that are connected in series between the ground and the voltage supply path.

In another exemplary aspect, a voltage supply method is provided that includes generating a plurality of discrete voltages, based on an input voltage, selecting at least a first voltage from the plurality of discrete voltages as a supply voltage, filtering the voltage supply to generate a filtered voltage supply, switching between a connection and a disconnection of a voltage supply path to and from a ground with a capacitor interposed therebetween, and supplying the filtered voltage supply via the voltage supply path.

According to the exemplary aspects of the present disclosure, the characteristic degradation of multiple discrete voltages supplied to an amplifier is suppressed.

### BRIEF DESCRIPTION OF DRAWINGS

FIG. 1A is a graph illustrating an example of power supply voltage transition in an average power tracking (APT) mode in an exemplary aspect.

FIG. 1B is a graph illustrating an example of power supply voltage transition in an analog envelope tracking (A-ET) mode in an exemplary aspect.

FIG. 1C is a graph illustrating an example of power supply voltage transition in a digital envelope tracking (D-ET) mode in an exemplary aspect.

FIG. 2 is a circuit configuration diagram of a communication device according to an exemplary embodiment.

FIG. 3 is a circuit configuration diagram of a pre-regulator circuit, a switched-capacitor circuit, a power modulation circuit (supply modulator), a filter circuit, and an APT switch circuit according to the exemplary embodiment.

FIG. 4 is a circuit configuration diagram of a digital control circuit according to the exemplary embodiment.

FIG. 5 is a flowchart illustrating a voltage supply method performed by a tracker circuit according to the exemplary embodiment.

FIG. 6 is a flowchart illustrating details of Step S107 in FIG. 5.

FIG. 7 is a plan view of a tracker module according to the exemplary embodiment.

FIG. 8 is a plan view of the tracker module according to the exemplary embodiment.

FIG. 9 is a cross-sectional view of the tracker module according to the exemplary embodiment.

FIG. 10 is a circuit configuration diagram of an APT switch circuit according to a modification.

FIG. 11 is a circuit configuration diagram of a communication device according to another exemplary embodiment.

### DETAILED DESCRIPTION OF EXEMPLARY EMBODIMENTS

In the following, exemplary embodiments of the present disclosure will be described in detail using the drawings. It is noted that all of the exemplary embodiments described below are intended to represent generic or specific examples. The numerical values, shapes, materials, constituent elements, and arrangement and connection forms of the constituent illustrated in the following exemplary embodiments are examples and are not intended to limit the present disclosure.

Each drawing is a schematic diagram with emphasis, omissions, or proportions adjusted as appropriate to illustrate the present disclosure. The drawings are not always exact depictions and can differ from actual shapes, positional relationships, and proportions. In each diagram, the same symbols are assigned to substantially identical configurations, and redundant descriptions can be omitted or simplified.

In each of the following drawings and for purposes of this disclosure, the x-axis and y-axis are axes that are orthogonal to each other in a plane parallel to the main surface of a module laminate. In an exemplary aspect, when a module laminate has a rectangular shape in a plan view, the x-axis is parallel to a first side of the module laminate, and the y-axis is parallel to a second side of the module laminate orthogonal to the first side. Moreover, the z-axis is the axis perpendicular to the main surface of the module laminate. The positive direction of the z-axis indicates the upward direction, and the negative direction of the z-axis indicates the downward direction.

Regarding circuit configurations in the present disclosure, the term “connected” includes not only direct connections formed by connection terminals, wiring conductors, or both, but also electrical connections formed via other circuit elements. Moreover, the phrase “Connected between A and B” generally refers to a connection that is established between A and B, linking both, and also that a connection is made in series with a path between A and B. The phrase “path between A and B” refers to a path formed by conductors that electrically connect A to B.

In the component arrangement of the present disclosure, the phrase “a component is arranged in or on a laminate” includes a component being arranged on the main surface of the laminate and a component being arranged within the laminate. The phrase “a component is arranged on the main surface of a laminate” includes, in addition to a component being arranged in contact with the main surface of the laminate, a component being arranged above the main surface without being in contact with the main surface (for example, a component is stacked on top of another component arranged in contact with the main surface). Moreover, the phrase “a component is arranged on the main surface of a laminate” can include a component being arranged in a recess formed in the main surface. The phrase “a component is arranged within a laminate” includes not only a component being encapsulated within a module laminate but also a case where the entire component is arranged between the two main surfaces of the laminate but part of the component remains uncovered, and a case where only a portion of the component is arranged within the laminate.

In the component arrangement of the present disclosure, the phrase “plan view of the module laminate” refers to viewing an object or a component as an orthographic projection onto the xy-plane from the positive z-axis side. The phrase “A overlaps B in a plan view” means that at least part of the area of A orthographically projected onto the xy-plane overlaps at least part of the area of B orthographically projected onto the xy-plane. In addition, “A is arranged between B and C” means that at least one line segment, among multiple line segments connecting freely chosen points in B to freely chosen points in C, passes through A.

In the component arrangement of the present disclosure, the phrase “A is arranged adjacent to B” means that A and B are arranged in close proximity, that no other circuit components are present in the space where A faces B according to an exemplary aspect. In other words, the phrase “A is arranged adjacent to B” means that none of the multiple line segments from freely chosen points on the surface of A facing B to B, along the normal direction of that surface, pass through any circuit component other than A and B. In this case, a circuit component refers to a component that includes an active element, a passive element, or both. In other words, the term “circuit component” includes active components and passive components but does not include electromechanical components. The active components include transistors or diodes. The passive components include inductors, transformers, capacitors, or resistors. The electromechanical components include terminals, connectors, or wiring lines.

In the present disclosure, the term “terminal” refers to a point at which a conductor in an element terminates. It is also noted that when the impedance of the path between elements is sufficiently low, the terminal is interpreted not just as a single point but as any point on the path between the elements or as the entire path.

For purposes of this disclosure, the terms indicating relationships between elements, such as “parallel” and “perpendicular”, and terms describing the shapes of elements, such as “rectangle”, as well as numerical ranges are not intended to express exact meanings only but also to include substantially equivalent ranges, such as errors of a few percent.

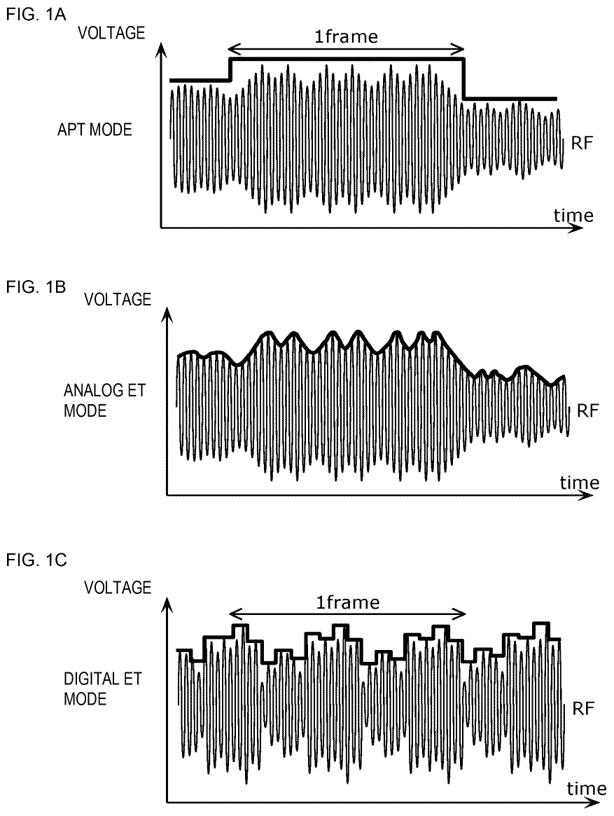

First, as a technique for highly efficient amplification of radio frequency (RF) signals, a tracking mode will be described in which a power amplifier (PA) is supplied with a power supply voltage that is dynamically regulated over time on the basis of an RF signal. The tracking mode is a mode in which the power supply voltage applied to a power amplifier circuit is dynamically regulated. There are several types of tracking modes, but in the following, an average power tracking (APT) mode and an envelope tracking (ET) mode (including an analog ET mode and a digital ET mode) will be described with reference to FIGS. 1A to 1C. In FIGS. 1A to 1C, the horizontal axis represents time, and the vertical axis represents voltage. The thick solid line represents power supply voltage, and the thin solid line (waveform) represents modulation signal.

FIG. 1A is a graph illustrating an example of power supply voltage transition in the APT mode. In the APT mode, the power supply voltage is varied to multiple discrete voltage levels in units of one frame on the basis of average power.

For purposes of this disclosure, frames refer to units that form an RF signal (modulation signal). For example, in the 5th Generation New Radio (5G NR) and Long Term Evolution (LTE), a frame includes 10 subframes, each subframe includes multiple slots, and each slot includes multiple symbols. In an exemplary aspect, the subframe length is 1 ms, and the frame length is 10 ms.

It is also noted that the mode in which the voltage level is varied in units of one frame or larger on the basis of average power is referred to as APT mode, and the APT mode is distinguished from the mode in which the voltage level is varied in units smaller than one frame (for example, a subframe, a slot, or a symbol). For example, the mode in which the voltage level is varied in units of a symbol is referred to as symbol power tracking (SPT) mode and is distinguished from the APT mode.

FIG. 1B is a graph illustrating an example of power supply voltage transition in the analog ET mode. In the analog ET mode, the envelope of the modulation signal is tracked by continuously varying the power supply voltage on the basis of the envelope signal.

An envelope signal is a signal that indicates the envelope of a modulation signal. An envelope value is expressed, for example, as the square root of (I²+Q²). In this case, (I, Q) represents a constellation point. A constellation point is a point that represents, on a constellation a signal modulated by digital diagram, modulation. (I, Q) is determined by a baseband integrated circuit (BBIC), for example, on the basis of transmission information, for example.

FIG. 1C is a graph illustrating an example of power supply voltage transition in the digital ET mode. In the digital ET mode, the envelope of a modulation is tracked by varying the power supply voltage to multiple discrete voltage levels within a single frame on the basis of the envelope signal.

### Exemplary Embodiments

The following is a description of exemplary embodiments. A communication device 8 according to the present exemplary embodiment can be used to provide wireless connections. For example, the communication device 8 can be mounted in user equipment (UE) in cellular networks, such as cell phones, smartphones, tablet computers, and wearable devices. In another example, the communication device 8 can be implemented to provide wireless connections to Internet of Things (IoT) sensors and devices, medical/healthcare devices, cars, unmanned aerial vehicles (UAVs) (commonly known as drones), and automated guided vehicles (AGVs). In yet another example, the communication device 8 can be implemented to provide wireless connections at a wireless access point or a wireless hotspot.

### 1.1 Circuit Configuration of Communication Device 8

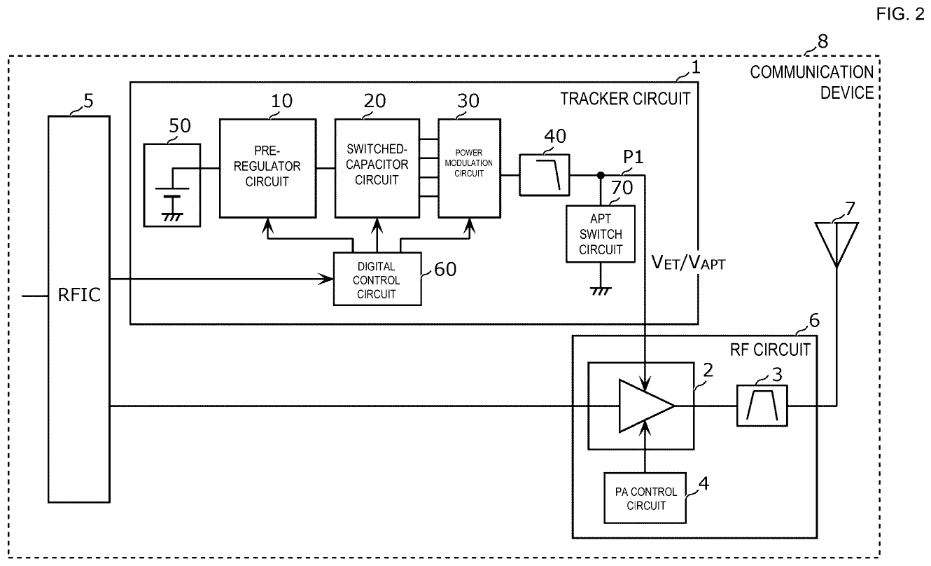

First, the circuit configuration of the communication device 8 will be described with reference to FIG. 2. FIG. 2 is a circuit configuration diagram of the communication device 8 according to the present exemplary embodiment. As illustrated in FIG. 2, the communication device 8 according to the present exemplary embodiment includes a tracker circuit 1, a radio frequency (RF) circuit 6, a radio frequency integrated circuit (RFIC) 5, and an antenna 7.

The tracker circuit 1 is configured to supply a power supply voltage V_{ET} based on the digital ET mode and a power supply voltage V_{APT} based on the APT mode in a selective manner to a power amplifier 2 included in the RF circuit 6. In the digital ET mode, at least one voltage is selected from multiple discrete voltages in units smaller than one frame on the basis of the envelope signal. In contrast, in the APT mode, at least one voltage is selected from the multiple discrete voltages in units of one frame on the basis of average power.

It is noted that in FIG. 2, the tracker circuit 1 supplies the power supply voltages to the one power amplifier 2, but the tracker circuit 1 can supply different power supply voltages to multiple power amplifiers.

As illustrated in FIG. 2, the tracker circuit 1 includes a pre-regulator circuit 10, a switched-capacitor circuit 20, a power modulation circuit 30, a filter circuit 40, a direct current (DC) power source 50, and a digital control circuit 60.

The pre-regulator circuit 10 includes a power inductor and a switch. A power inductor is an inductor used to increase, decrease, or both increase and decrease direct current (DC) voltage. A power inductor is arranged in series with a DC path. Note that a power inductor can be connected (e.g., arranged in parallel) between a DC path and ground. The pre-regulator circuit 10 can use a power inductor to convert the input voltage into a first voltage. Such a pre-regulator circuit 10 can also be referred to as a magnetic regulator or a DC/DC converter.

The switched-capacitor circuit 20 includes multiple capacitors and multiple switches and can generate multiple discrete second voltages from the first voltage from the pre-regulator circuit 10. The multiple discrete second voltages have multiple respective discrete voltage levels. The switched-capacitor circuit 20 can also be referred to as a switched-capacitor voltage ladder.

For purposes of this disclosure, the pre-regulator circuit 10 and the switched-capacitor circuit 20 are an example of a first switch circuit and are configured to generate the multiple discrete voltages on the basis of the input voltage.

Moreover, the power modulation circuit 30 is an example of a second switch circuit and is configured to modulate the power supply voltage by selecting at least one voltage from the multiple second voltages generated by the switched-capacitor circuit 20 and outputting the at least one voltage to the power amplifier 2. The modulated power supply voltage is supplied to the power amplifier 2 via a voltage supply path P1. The power modulation circuit 30 is controlled on the basis of a digital control signal.

As further shown, the filter circuit 40 is connected between the power modulation circuit 30 and the power amplifier 2. The filter circuit 40 is a pulse shaping network and is configured to filter a signal (a second voltage) from the power modulation circuit 30.

The DC power source 50 is configured to supply DC voltage to the pre-regulator circuit 10. For example, a rechargeable battery can be used as the DC power source 50, but the DC power source 50 is not limited to this configuration in alternative aspects.

The digital control circuit 60 is configured to control the pre-regulator circuit 10, the switched-capacitor circuit 20, the power modulation circuit 30, and an APT switch circuit 70 on the basis of a digital control signal from the RFIC 5.

The APT switch circuit 70 is an example of a third switch circuit and is connected between ground and the voltage supply path P1 between the filter circuit 40 and the power amplifier 2.

Note that, in some exemplary examples, the tracker circuit 1 does not include at least one of the pre-regulator circuit 10, the switched-capacitor circuit 20, the power modulation circuit 30, the filter circuit 40, the DC power source 50, the digital control circuit 60, and the APT switch circuit 70. For example, the tracker circuit 1 does not include the DC power source 50 according to an exemplary aspect. Moreover, any combination of the pre-regulator circuit 10, the switched-capacitor circuit 20, the power modulation circuit 30, the filter circuit 40, and the APT switch circuit 70 can be integrated into a single circuit.

The RF circuit 6 is configured to transfer RF signals between the antenna 7 and the RFIC 5. The RF circuit 6 includes the power amplifier 2, a filter 3, and a power amplifier (PA) control circuit 4.

In the present exemplary embodiment, RF signals are wireless communication signals in communication networks established using radio access technology (RAT). RF signals can be signals in the frequency band below six gigahertz or can be millimeter-wave signals.

Note that millimeter wave signals generally refer to signals in the range of 30 to 300 GHz but can also be signals in the range of 24.25 to 52.6 GHz (Frequency Region (FR) 2 in 5GNR).

Examples of communication systems include the 5th Generation New Radio (5GNR) system, the Long Term Evolution (LTE) system, and wireless local area network (WLAN) systems.

The power amplifier 2 is connected between the RFIC 5 and the filter 3. Furthermore, the power amplifier 2 is connected to the tracker circuit 1 and the PA control circuit 4. The power amplifier 2 can use the voltage received from the tracker circuit 1 to amplify an RF signal received from the RFIC 5.

The filter 3 is connected between the power amplifier 2 and the antenna 7. The filter 3 has a pass band that includes the frequency bands used for transmitting RF signals. The frequency bands used for transmitting RF signals are predefined by standardizing bodies (for example, 3rd Generation Partnership Project (3GPP®) and Institute of Electrical and Electronics Engineers (IEEE)).

In the exemplary aspect, the PA control circuit 4 is configured to control the power amplifier 2. In an exemplary aspect, the PA control circuit 4 can supply a bias control signal to the power amplifier 2.

The RFIC 5 is an example of a signal processing circuit that processes RF signals. In an exemplary aspect, the RFIC 5 processes an input transmission signal using, for example, up-conversion and supplies the RF transmission signal generated by performing the signal processing to the power amplifier 2. The RFIC 5 also has a control unit that controls the tracker circuit 1. It is noted that some or all of the functions of the RFIC 5 serving as the control unit can be implemented outside of the RFIC 5.

It is also noted that the circuit configuration of the RF circuit 6 illustrated in FIG. 2 is an example and is not limited to this configuration. For example, the RF circuit 6 can include multiple filters corresponding to multiple frequency bands and can also include a switch to switch between the multiple filters.

The antenna 7 is configured to transmit the RF signal input from the power amplifier 2 via the filter 3. In some exemplary examples, the antenna 7 is not included in the communication device 8.

It is noted that the circuit configuration of the communication device 8 illustrated in FIG. 2 is an example and is not so limited. For example, the communication device 8 can include a baseband signal processing circuit that processes signals using an intermediate frequency band that is lower in frequency than the RF signals transferred by the RF circuit 6. For example, the communication device 8 can also include a receive path. In this case, a low-noise amplifier and a filter, for example, can be connected to the receive path.

### 1.2 Circuit Configuration of Tracker Circuit 1

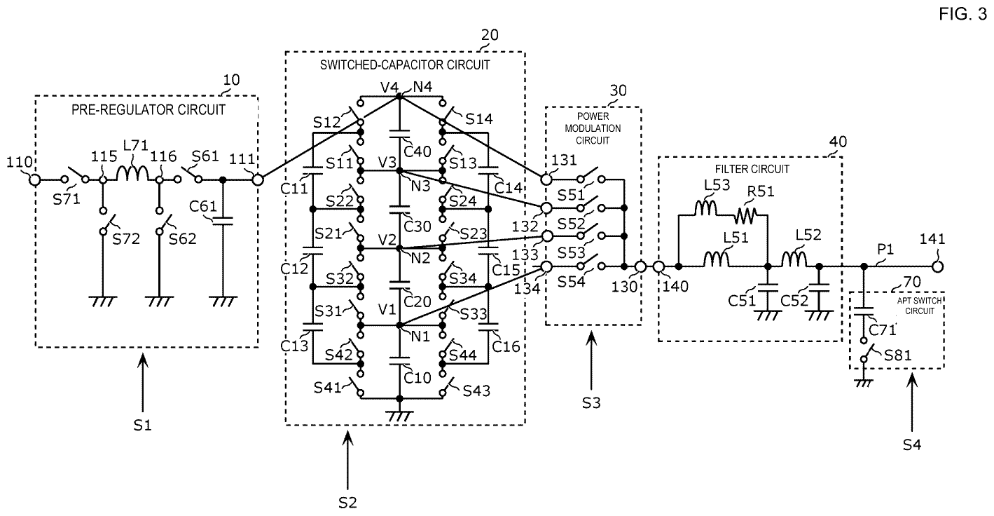

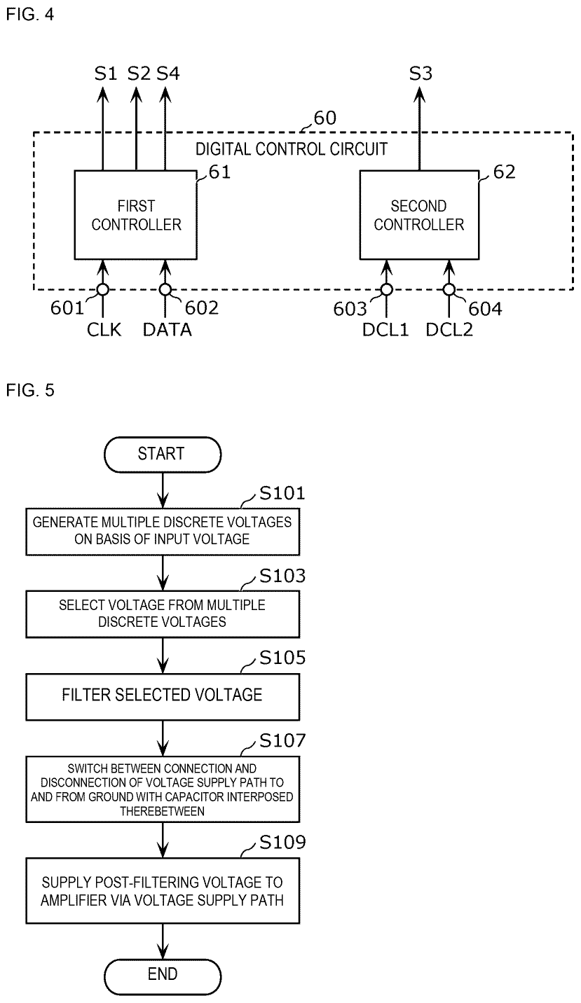

Next, the circuit configuration of the pre-regulator circuit 10, the switched-capacitor circuit 20, the power modulation circuit 30, the filter circuit 40, the digital control circuit 60, and the APT switch circuit 70 included in the tracker circuit 1 will be described with reference to FIGS. 3 and 4. FIG. 3 is a circuit configuration diagram of the pre-regulator circuit 10, the switched-capacitor circuit 20, the power modulation circuit 30, the filter circuit 40, and the APT switch circuit 70 according to the present exemplary embodiment. FIG. 4 is a circuit configuration diagram of the digital control circuit 60 according to the present exemplary embodiment.

FIGS. 3 and 4 illustrate example circuit configurations, and the pre-regulator circuit 10, the switched-capacitor circuit 20, the power modulation circuit 30, the filter circuit 40, the digital control circuit 60, and the APT switch circuit 70 can be implemented using any of a wide variety of circuit implementations and circuit techniques. Thus, the description of each circuit provided below is not to be interpreted in a limited manner.

### 1.2.1 Circuit Configuration of Switched-Capacitor Circuit 20

First, the circuit configuration of the switched-capacitor circuit 20 will be described. The switched-capacitor circuit 20 includes, as illustrated in FIG. 3, capacitors C11 to C16, capacitors C10, C20, C30, and C40, and switches S11 to S14, S21 to S24, S31 to S34, and S41 to S44. Energy and electric charge are input at nodes N1 to N4 from the pre-regulator circuit 10 into the switched-capacitor circuit 20 and taken out at the nodes N1 to N4 from the switched-capacitor circuit 20 to the power modulation circuit 30.

Each of the capacitors C11 to C16 are configured to function as a flying capacitor, which can also be referred to as a transfer capacitor. That is, each of the capacitors C11 to C16 is used to increase or decrease the first voltage supplied from the pre-regulator circuit 10. In some exemplary aspects, the capacitors C11 to C16 cause electric charge to move between the capacitors C11 to C16 and the four nodes N1 to N4 so that voltages V1 to V4 (voltages relative to ground potential) satisfying V1:V2:V3:V4=1:2:3:4 are maintained at the nodes N1 to N4. These voltages V1 to V4 correspond to multiple second voltages having multiple respective discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to the one end of the switch S21 and the one end of the switch S22. The other of the two electrodes of the capacitor C12 is connected to one end of the switch S31 and one end of the switch S32.

The capacitor C13 has two electrodes. One of the two electrodes of the capacitor C13 is connected to the one end of the switch S31 and the one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to the one end of the switch S23 and the one end of the switch S24. The other of the two electrodes of the capacitor C15 is connected to one end of the switch S33 and one end of the switch S34.

The capacitor C16 has two electrodes. One of the two electrodes of the capacitor C16 is connected to the one end of the switch S33 and the one end of the switch S34. The other of the two electrodes of the capacitor C16 is connected to one end of the switch S43 and one end of the switch S44.

The set of the capacitors C11 and C14, the set of the capacitors C12 and C15, and the set of the capacitors C13 and C16 can each be charged and discharged in a complementary manner by repeating a first phase and a second phase.

In an exemplary aspect, in the first phase, the switches S12, S13, S22, S23, S32, S33, S42, and S43 are turned on. As a result, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

In contrast, in the second phase, the switches S11, S14, S21, S24, S31, S34, S41, and S44 are turned on. As a result, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

These first and second phases are repeated so that, for example, while one of the capacitors C12 and C15 is being charged from the node N2, the other of the capacitors C12 and C15 can be discharged to the capacitor C30. That is, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner by repeating the first phase and the second phase.

Each of the capacitors C10, C20, C30, and C40 can be configured to function as a smoothing capacitor. That is, each of the capacitors C10, C20, C30, and C40 is used to hold and smooth the voltages V1 to V4 at the nodes N1 to N4.

The capacitor C10 is connected between the node N1 and ground. In an exemplary aspect, one of two electrodes of the capacitor C10 is connected to the node N1. In contrast, the other of the two electrodes of the capacitor C10 is connected to ground.

The capacitor C20 is connected between the nodes N2 and N1. In an exemplary aspect, one of two electrodes of the capacitor C20 is connected to the node N2. In contrast, the other of the two electrodes of the capacitor C20 is connected to the node N1.

The capacitor C30 is connected between the nodes N3 and N2. In an exemplary aspect, one of two electrodes of the capacitor C30 is connected to the node N3. In contrast, the other of the two electrodes of the capacitor C30 is connected to the node N2.

The capacitor C40 is connected between the nodes N4 and N3. In an exemplary aspect, one of two electrodes of the capacitor C40 is connected to the node N4. In contrast, the other of the two electrodes of the capacitor C40 is connected to the node N3.

The switch S11 is connected between the one of the two electrodes of the capacitor C11 and the node N3. In an exemplary aspect, the one end of the switch S11 is connected to the one of the two electrodes of the capacitor C11. In contrast, the other end of the switch S11 is connected to the node N3.

The switch S12 is connected between the one of the two electrodes of the capacitor C11 and the node N4. In an exemplary aspect, the one end of the switch S12 is connected to the one of the two electrodes of the capacitor C11. In contrast, the other end of the switch S12 is connected to the node N4.

The switch S21 is connected between the one of the two electrodes of the capacitor C12 and the node N2. In an exemplary aspect, the one end of the switch S21 is connected to the one of the two electrodes of the capacitor C12 and the other of the two electrodes of the capacitor C11. In contrast, the other end of the switch S21 is connected to the node N2.

The switch S22 is connected between the one of the two electrodes of the capacitor C12 and the node N3. In an exemplary aspect, the one end of the switch S22 is connected to the one of the two electrodes of the capacitor C12 and the other of the two electrodes of the capacitor C11. In contrast, the other end of the switch S22 is connected to the node N3.

The switch S31 is connected between the other of the two electrodes of the capacitor C12 and the node N1. In an exemplary aspect, the one end of the switch S31 is connected to the other of the two electrodes of the capacitor C12 and the one of the two electrodes of the capacitor C13. In contrast, the other end of the switch S31 is connected to the node N1.

The switch S32 is connected between the other of the two electrodes of the capacitor C12 and the node N2. In an exemplary aspect, the one end of the switch S32 is connected to the other of the two electrodes of the capacitor C12 and the one of the two electrodes of the capacitor C13. In contrast, the other end of the switch S32 is connected to the node N2. That is, the other end of the switch S32 is connected to the other end of the switch S21.

The switch S41 is connected between the other of the two electrodes of the capacitor C13 and ground. In an exemplary aspect, the one end of the switch S41 is connected to the other of the two electrodes of the capacitor C13. In contrast, the other end of the switch S41 is connected to ground.

The switch S42 is connected between the other of the two electrodes of the capacitor C13 and the node N1. In an exemplary aspect, one end of the switch S42 is connected to the other of the two electrodes of the capacitor C13. In contrast, the other end of the switch S42 is connected to the node N1. That is, the other end of the switch S42 is connected to the other end of the switch S31.

The switch S13 is connected between the one of the two electrodes of the capacitor C14 and the node N3. In an exemplary aspect, the one end of the switch S13 is connected to the one of the two electrodes of the capacitor C14. In contrast, the other end of the switch S13 is connected to the node N3. That is, the other end of the switch S13 is connected to the other end of the switch S11 and the other end of the switch S22.

The switch S14 is connected between the one of the two electrodes of the capacitor C14 and the node N4. In an exemplary aspect, the one end of the switch S14 is connected to the one of the two electrodes of the capacitor C14. In contrast, the other end of the switch S14 is connected to the node N4. That is, the other end of the switch S14 is connected to the other end of the switch S12.

The switch S23 is connected between the one of the two electrodes of the capacitor C15 and the node N2. In an exemplary aspect, the one end of the switch S23 is connected to the one of the two electrodes of the capacitor C15 and the other of the two electrodes of the capacitor C14. In contrast, the other end of the switch S23 is connected to the node N2. That is, the other end of the switch S23 is connected to the other end of the switch S21 and the other end of the switch S32.

The switch S24 is connected between the one of the two electrodes of the capacitor C15 and the node N3. In an exemplary aspect, the one end of the switch S24 is connected to the one of the two electrodes of the capacitor C15 and the other of the two electrodes of the capacitor C14. In contrast, the other end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. In an exemplary aspect, the one end of the switch S33 is connected to the other of the two electrodes of the capacitor C15 and the one of the two electrodes of the capacitor C16. In contrast, the other end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. In an exemplary aspect, the one end of the switch S34 is connected to the other of the two electrodes of the capacitor C15 and the one of the two electrodes of the capacitor C16. In contrast, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and ground. In an exemplary aspect, the one end of the switch S43 is connected to the other of the two electrodes of the capacitor C16. In contrast, the other end of the switch S43 is connected to ground.

The switch S44 is connected between the other of the two electrodes of the capacitor C16 and the node N1. In an exemplary aspect, the one end of the switch S44 is connected to the other of the two electrodes of the capacitor C16. In contrast, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched between on and off in a complementary manner on the basis of a control signal S2. In an exemplary aspect, in the first phase, the first set of switches is turned on, and the second set of switches is turned off. In contrast, in the second phase, the first set of switches is turned off, and the second set of switches is turned on.

For example, charging from the capacitors C11 to C13 to the capacitors C10 to C40 is performed in one of the first and second phases, and charging from the capacitors C14 to C16 to the capacitors C10 to C40 is performed in the other of the first and second phases. That is, since the capacitors C10 to C40 are constantly charged from the capacitors C11 to C13 or the capacitors C14 to C16, even in a case where current flows at high speed from the nodes N1 to N4 to the power modulation circuit 30, the nodes N1 to N4 are replenished with electric charge at high speed, thereby suppressing potential variations at the nodes N1 to N4.

By operating in this manner, the switched-capacitor circuit 20 can maintain approximately equal voltages at both ends of each of the capacitors C10, C20, C30, and C40. In an exemplary aspect, the voltages V1 to V4 (voltages relative to ground potential) that satisfy V1:V2:V3:V4=1:2:3:4 are maintained at the four nodes labeled V1 to V4. The voltage levels of the voltages V1 to V4 correspond to the multiple discrete voltage levels that the switched-capacitor circuit 20 can supply to the power modulation circuit 30.

It is noted that the voltage ratio (V1:V2:V3:V4) is not limited to (1:2:3:4). For example, the voltage ratio (V1:V2:V3:V4) can be (1:2:4:8) in an alternative aspect.

Moreover, the configuration of the switched-capacitor circuit 20 illustrated in FIG. 3 is an example and is not so limited. In FIG. 3, the switched-capacitor circuit 20 is configured to supply voltages with four discrete voltage levels, but it is not limited to this configuration. The switched-capacitor circuit 20 can be configured to supply voltages with any number of discrete voltage levels, starting from two. For example, when the switched-capacitor circuit 20 supplies voltages with two discrete voltage levels, it is sufficient that the switched-capacitor circuit 20 have at least the capacitors C12 and C15 and the switches S21 to S24 and S31 to S34.

### 1.2.2 Circuit Configuration of Power Modulation Circuit 30

Next, the circuit configuration of the power modulation circuit 30 will be described. The power modulation circuit 30 is connected to the digital control circuit 60. As illustrated in FIG. 3, the power modulation circuit 30 includes input terminals 131 to 134, switches S51 to S54, and an output terminal 130.

The output terminal 130 is connected to the filter circuit 40. The output terminal 130 is a terminal for supplying power supply voltage, which is selected from the voltages V1 to V4, to the power amplifier 2 via the filter circuit 40.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20.

The switch S51 is connected between the input terminal 131 and the output terminal 130. In an exemplary aspect, the switch S51 has a terminal connected to the input terminal 131 and a terminal connected to the output terminal 130. In this connection configuration, the switch S51 can be switched between on and off by a control signal S3 to switch between connection and disconnection of the input terminal 131 and the output terminal 130.

The switch S52 is connected between the input terminal 132 and the output terminal 130. In an exemplary aspect, the switch S52 has a terminal connected to the input terminal 132 and a terminal connected to the output terminal 130. In this connection configuration, the switch S52 can be switched between on and off by the control signal S3 to switch between connection and disconnection of the input terminal 132 and the output terminal 130.

The switch S53 is connected between the input terminal 133 and the output terminal 130. In an exemplary aspect, the switch S53 has a terminal connected to the input terminal 133 and a terminal connected to the output terminal 130. In this connection configuration, the switch S53 can be switched between on and off by the control signal S3 to switch between connection and disconnection of the input terminal 133 and the output terminal 130.

The switch S54 is connected between the input terminal 134 and the output terminal 130. In an exemplary aspect, the switch S54 has a terminal connected to the input terminal 134 and a terminal connected to the output terminal 130. In this connection configuration, the switch S54 can be switched between on and off by the control signal S3 to switch between connection and disconnection of the input terminal 134 and the output terminal 130.

These switches S51 to S54 are controlled to be turned on exclusively. That is, only one of the switches S51 to S54 is turned on, and the rest of the switches S51 to S54 are turned off. This allows the power modulation circuit 30 to output one voltage selected from the voltages V1 to V4.

It is noted that the configuration of the power modulation circuit 30 illustrated in FIG. 3 is an example and is not so limited. In particular, the switches S51 to S54 can be of any configuration, as long as any of the four input terminals 131 to 134 can be selected and connected to the output terminal 130. For example, the power modulation circuit 30 can further include a switch connected between the switches S51 to S53 and the switch S54 and output terminal 130. For example, the power modulation circuit 30 can further include a switch connected between the switches S51 and S52 and the switches S53 and S54 and output terminal 130.

It is also noted that when voltages with two discrete voltage levels are supplied from the switched-capacitor circuit 20, it is sufficient that the power modulation circuit 30 include at least two out of the switches S51 to S54.

### 1.2.3 Circuit Configuration of Pre-Regulator Circuit 10

First, the configuration of the pre-regulator circuit 10 will be described. As illustrated in FIG. 3, the pre-regulator circuit 10 includes an input terminal 110, an output terminal 111, inductor connection terminals 115 and 116, switches S61, S62, S71, and S72, a power inductor L71, and a capacitor C61.

According to the exemplary aspect, the input terminal 110 is an input terminal for DC voltage. That is, the input terminal 110 is a terminal for receiving input voltage from the DC power source 50.

The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110 and the one end of the power inductor L71. In an exemplary aspect, the switch S71 has a terminal connected to the input terminal 110 and a terminal connected to the one end of the power inductor L71 with the inductor connection terminal 115 interposed therebetween. In this connection configuration, the switch S71 can be switched between on and off on the basis of a control signal S1 to switch between connection and disconnection of the input terminal 110 and the one end of the power inductor L71.

The switch S72 is connected between the one end of the power inductor L71 and ground. In an exemplary aspect, the switch S72 has a terminal connected to the one end of the power inductor L71 with the inductor connection terminal 115 interposed therebetween, and a terminal connected to ground. In this connection configuration, the switch S72 can be switched between on and off on the basis of the control signal S1 to switch between connection and disconnection of the one end of the power inductor L71 and ground.

The switch S61 is connected between the other end of the power inductor L71 and the output terminal 111. In an exemplary aspect, the switch S61 has a terminal connected to the other end of the power inductor L71 with the inductor connection terminal 116 interposed therebetween, and a terminal connected to the output terminal 111. In this connection configuration, the switch S61 can be switched between on and off on the basis of the control signal S1 to switch between connection and disconnection of the other end of the power inductor L71 and the output terminal 111.

The switch S62 is connected between the other end of the power inductor L71 and ground. In an exemplary aspect, the switch S62 has a terminal connected to the other end of the power inductor L71 with the inductor connection terminal 116 interposed therebetween, and a terminal connected to ground. In this connection configuration, the switch S62 can be switched between on and off by the control signal S1 to switch between connection and disconnection of the other end of the power inductor L71 and ground.

One of two electrodes of the capacitor C61 is connected to the switch S61 and the output terminal 111. The other of the two electrodes of the capacitor C61 is connected to ground. Note that, in some exemplary examples, the capacitor C61 are not included in the pre-regulator circuit 10.

The pre-regulator circuit 10 configured in this manner can supply electric charge to the switched-capacitor circuit 20 via the output terminal 111.

According to the present exemplary embodiment, the pre-regulator circuit 10 is a buck-boost converter but can also be a buck converter or a boost converter. For example, in a case where the pre-regulator circuit 10 is a buck converter, the pre-regulator circuit 10 does not include the switches S61 and S62 in some exemplary examples. Moreover, for example, in a case where the pre-regulator circuit 10 is a boost converter, the pre-regulator circuit 10 does not include the switches S71 and S72.

### 1.2.4 Circuit Configuration of Filter Circuit 40

Next, the circuit configuration of the filter circuit 40 will be described. In the present exemplary embodiment, the filter circuit 40 has a low-pass response and is configured to filter voltage received via an input terminal 140 and output the filtered voltage to an output terminal 141. In an exemplary aspect, as illustrated in FIG. 3, the filter circuit 40 includes inductors L51 to L53, capacitors C51 and C52, a resistor R51, and the input terminal 140.

The input terminal 140 is an input terminal for the voltage selected by the power modulation circuit 30. That is, the input terminal 140 is a terminal for receiving a voltage selected from the multiple voltages V1 to V4.

The output terminal 141 is an output terminal for the power supply voltage V_{ET}/V_{APT}. That is, the output terminal 141 is a terminal for supplying the power supply voltage to the power amplifier 2.

In an exemplary aspect, the inductors L51 to L53, the capacitors C51 and C52, and the resistor R51 form a low pass filter (LPF). This configuration allows the filter circuit 40 to reduce a radio frequency (RF) component included in the power supply voltage.

It is noted that the configuration of the filter circuit 40 illustrated in FIG. 3 is an example and is not so limited. For example, the filter circuit 40 does not include the inductor L53 and the resistor R51 in some exemplary aspects. Moreover, for example, the filter circuit 40 can include an inductor connected to one of two electrodes of the capacitor C51 and can include an inductor connected to one of two electrodes of the capacitor C52. The filter circuit 40 can be partially or completely composed of parasitic reactance, parasitic resistance, or a combination of both. Parasitic reactance includes, for example, the inductance, capacitance, or both the inductance and capacitance of the metal wiring line (e.g., metal trace) connecting two nodes. Parasitic resistance includes, for example, the resistance of the metal wiring line connecting two nodes.

### 1.2.5 Circuit Configuration of APT Switch Circuit 70

Next, the circuit configuration of the APT switch circuit 70 will be described. As illustrated in FIG. 3, the APT switch circuit 70 includes a capacitor C71 and a switch S81, which are connected in series.

In an exemplary aspect, the capacitor C71 is configured to function as a so-called bypass capacitor and can ground the noise components of the signal flowing through the voltage supply path P1. One end of the capacitor C71 is connected to the voltage supply path P1, and the other end of the capacitor C71 is connected to the switch S81.

The switch S81 is connected between the capacitor C71 and ground. In an exemplary aspect, the switch S81 includes a terminal connected to the other end of the capacitor C71 and a terminal connected to ground. In this connection configuration, the switch S81 can be switched between on and off by a control signal S4 to switch between connection and disconnection of the voltage supply path P1 to and from ground with the capacitor C71 interposed therebetween.

It is noted that, in some exemplary examples, the on and off of the switch S81 is not switched instantaneously. For example, the switch S81 can be turned on gradually. This configuration suppresses changes in the power supply voltage (for example, voltage drop) caused by turning on the switch S81.

### 1.2.6 Circuit Configuration of Digital Control Circuit 60

Next, the circuit configuration of the digital control circuit 60 will be described. As illustrated in FIG. 4, the digital control circuit 60 includes a first controller 61, a second controller 62, and control terminals 601 to 604.

The first controller 61 can process a source-synchronous digital control signal received from the RFIC 5 via the control terminals 601 and 602 to generate the control signals S1, S2, and S4. The control signal S1 is a signal for controlling the on and off of the switches S61, S62, S71, and S72 included in the pre-regulator circuit 10. The control signal S2 is a signal for controlling the on and off of the switches S11 to S14, S21 to S24, S31 to S34, and S41 to S44 included in the switched-capacitor circuit 20. The control signal S4 is a signal for controlling the on and off of the switch S81 included in the APT switch circuit 70. Moreover, a feedback signal for controlling the pre-regulator circuit 10 can be input to the first controller 61.

It is noted that the digital control signal processed by the first controller 61 is not limited to source-synchronous digital control signals. For example, the first controller 61 can process clock-embedded digital control signals in alternative aspects. Moreover, the first controller 61 can generate a control signal for controlling the power modulation circuit 30.

In the present exemplary embodiment, one set of clock and data signals are used as the digital control signal for the pre-regulator circuit 10, the switched-capacitor circuit 20, and the APT switch circuit 70, but digital control signals are not so limited. For example, as digital control signals for the pre-regulator circuit 10, the switched-capacitor circuit 20, and the APT switch circuit 70, sets of clock and data signals can be used in a respective manner.

The second controller 62 processes digital control level (DCL) signals (DCL1, DCL2) received from the RFIC 5 via control terminals 603 and 604 to generate the control signal S3. The DCL signals (DCL1, DCL2) are generated by the RFIC 5 on the basis of the envelope signal or average power of the radio frequency (RF) signal. The control signal S3 is a signal for controlling the on and off of the switches S51 to S54 included in the power modulation circuit 30.

Each of the DCL signals (DCL1, DCL2) is a 1-bit signal. Each of the voltages V1 to V4 is represented by a combination of two 1-bit signals. For example, V1, V2, V3, and V4 are represented by “00”, “01”, “10”, and “11”, respectively. Gray code can be used to represent voltage levels.

Note that in the present exemplary embodiment, two digital control level signals are used to control the power modulation circuit 30. However, the number of digital control level signals is not limited to this configuration. For example, any number of digital control level signals can be used, such as one, three, or more, depending on the number of voltage levels each of which the power modulation circuit 30 can select in alternative aspects. Moreover, the digital control signal used to control the power modulation circuit 30 is not limited to digital control level signals.

### 1.3 Voltage Supply Method

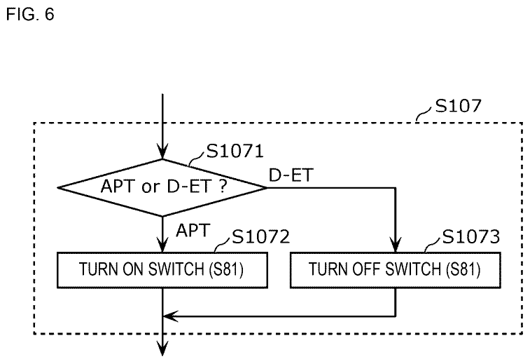

Next, a method for supplying voltage to the power amplifier 2 using the tracker circuit 1 configured as described above will be described with reference to FIGS. 5 and 6. FIG. 5 is a flowchart illustrating a voltage supply method according to the present exemplary embodiment. FIG. 6 is a flowchart illustrating details of step S107 in FIG. 5.

The pre-regulator circuit 10 and the switched-capacitor circuit 20 generate, on the basis of the control signals S1 and S2, multiple discrete voltages (second voltages) from the input voltage input from the DC power source 50 (S101).

The power modulation circuit 30 selects at least one voltage from the multiple discrete voltages on the basis of the control signal S3 (S103). For example, in a case where the control signal S3 is based on the digital ET mode, multiple discrete voltages are selected within one frame of the RF signal. For example, in a case where the control signal S3 is based on the APT mode, voltage selection is performed in units of one frame of the RF signal.

The filter circuit 40 filters the voltage selected by the power modulation circuit 30 (S105). This attenuates the radio-frequency noise included in the power supply voltage V_{ET}/V_{APT}.

The APT switch circuit 70 switches between connection and disconnection of the voltage supply path P1 to and from ground with the capacitor C71 interposed therebetween (S107). In an exemplary aspect, as illustrated in FIG. 6, in a case where at least one voltage is selected on the basis of the APT mode (APT in S1071), electrical conduction is allowed through the switch S81, which is connected between the capacitor C71 and ground (S1072). In contrast, in a case where at least one voltage is selected on the basis of the digital ET mode (D-ET in S1071), electrical conduction is not allowed through the switch S81, which is connected between the capacitor C71 and ground (S1073). For example, the digital control circuit 60 can receive a signal indicating the mode from the RFIC 5 and control the switch S81 between the electrical conduction (on) state and the electrical non-conduction (off) state on the basis of the received information. For example, the digital control circuit 60 can receive, from the RFIC 5, a signal indicating whether to turn on or off the switch S81.

Lastly, the tracker circuit 1 supplies the post-filtered voltage to the power amplifier 2 via the voltage supply path P1 (S109).

### 1.4 Component Arrangement in Tracker Module 100

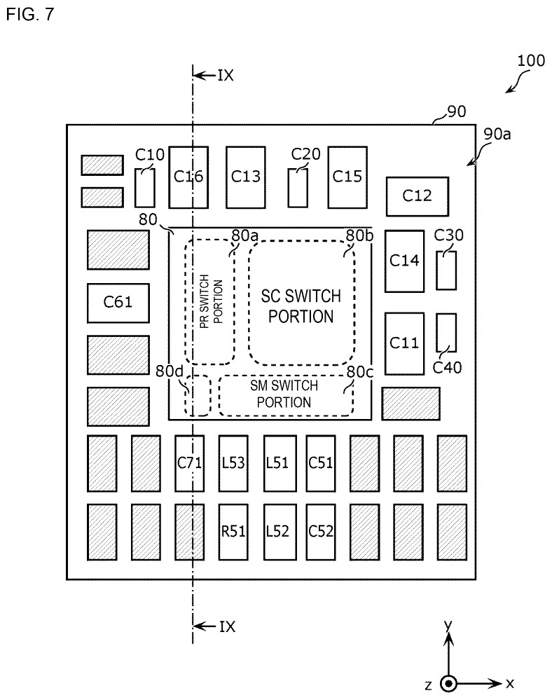

Next, as an example of implementation of the tracker circuit 1 configured as described above, a tracker module 100 in which the pre-regulator circuit 10, the switched-capacitor circuit 20, the power modulation circuit 30, the filter circuit 40, and the APT switch circuit 70 are implemented will be described with reference to FIGS. 7 to 9. Note that in the present example of implementation, the power inductor L71 included in the pre-regulator circuit 10 is not arranged in or on a module laminate 90 but can be arranged in or on the module laminate 90.

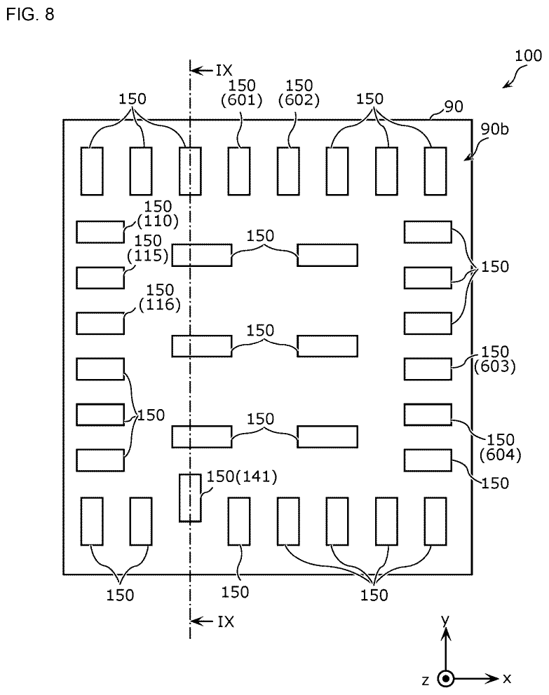

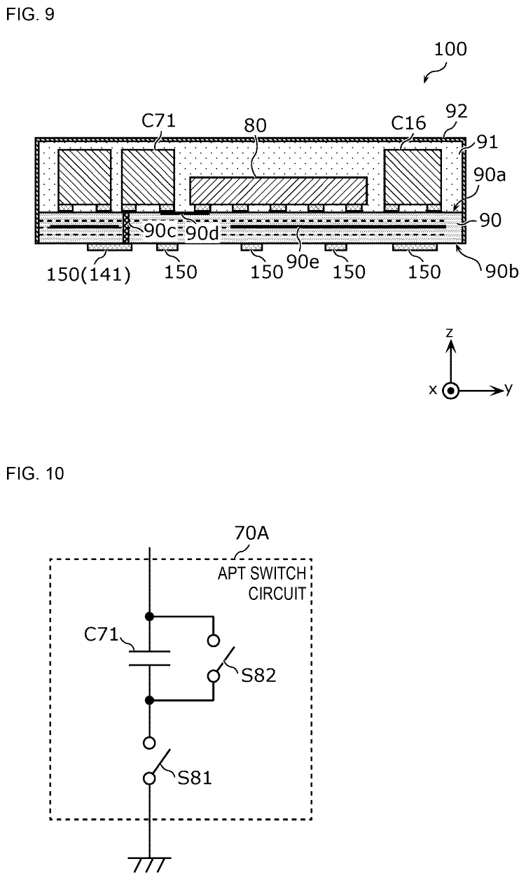

FIG. 7 is a plan view of the tracker module 100 according to the present exemplary embodiment. FIG. 8 is a plan view of the tracker module 100 according to the present exemplary embodiment and is a view looking through a main surface 90b side of the module laminate 90 from the z-axis positive side. FIG. 9 is a cross-sectional view of the tracker module 100 according to the present exemplary embodiment. The cross section of the tracker module 100 in FIG. 9 is the cross section taken along line IX-IX of each of FIGS. 7 and 8.

Note that in FIGS. 7 to 9, some of the wiring lines connecting multiple circuit components arranged in or on the module laminate 90 are omitted. In FIGS. 7 and 8, the illustration of a resin member 91 covering multiple circuit components and that of a shield electrode layer 92 covering the surface of the resin member 91 are omitted. In FIG. 7, the hatched blocks represent circuit components that may or may not present according to some exemplary aspects of the present disclosure.

In addition to multiple circuit components including active elements and passive elements included in the pre-regulator circuit 10, the switched-capacitor circuit 20, the power modulation circuit 30, the filter circuit 40, and the APT switch circuit 70 illustrated in in FIG. 2, the tracker module 100 includes the module laminate 90, the resin member 91, the shield electrode layer 92, and multiple land electrodes 150.

The module laminate 90 has a main surface 90a and the main surface 90b, which face each other. The main surface 90a and the main surface 90b are an example of a first main surface and an example of a second main surface, respectively. For example, a via conductor 90c, a wiring line 90d, and a ground plane 90e are formed in the module laminate 90 and on the main surface 90a. Note that in FIGS. 7 and 8, the module laminate 90 has a rectangular shape in plan view, but it is not limited to this shape and can be other shaped in alternative aspects.

As the module laminate 90, for example, a low temperature co-fired ceramics (LTCC) substrate or high temperature co-fired ceramics (HTCC) substrate having a multilayer structure of multiple dielectric layers, a component-embedded board, a substrate having a redistribution layer (RDL), or a printed circuit board can be used. However, it is noted the module laminate 90 is not limited to these examples.

On the main surface 90a, an integrated circuit 80, the capacitors C10 to C16, C20, C30, C40, C51, C52, C61, and C71, the inductors L51 to L53, the resistor R51, and the resin member 91 are arranged.

The integrated circuit 80 has a PR switch portion 80a, an SC switch portion 80b, an SM switch portion 80c, and an APT switch portion 80d. The PR switch portion 80a includes the switches S61, S62, S71, and S72. The SC switch portion 80b includes the switches S11 to S14, S21 to S24, S31 to S34, and S41 to S44. The SM switch portion 80c includes the switches S51 to S54. The APT switch portion 80d includes the switch S81.

Note that in FIG. 7, the PR switch portion 80a, the SC switch portion 80b, the SM switch portion 80c, and the APT switch portion 80d are included in the integrated circuit 80, which is a single integrated circuit. According to an exemplary aspect of the disclosure, the PR switch portion 80a, the SC switch portion 80b, the SM switch portion 80c, and the APT switch portion 80d are not included in the integrated circuit 80, which is a single integrated circuit. For example, the PR switch portion 80a and the SC switch portion 80b can be included in a single integrated circuit, and the SM switch portion 80c and the APT switch portion 80d can be included in another integrated circuit. For example, the SC switch portion 80b, the SM switch portion 80c, and the APT switch portion 80d can be included in a single integrated circuit, and the PR switch portion 80a can be included in another integrated circuit. Moreover, the PR switch portion 80a, the SM switch portion 80c, and the APT switch portion 80d can be included in a single integrated circuit, and the SC switch portion 80b can be included in another integrated circuit. For example, the PR switch portion 80a, the SC switch portion 80b, the SM switch portion 80c, and the APT switch portion 80d can be included in four integrated circuits separately. Note that the multiple integrated circuits can be manufactured at different process technology nodes.

Moreover, in FIG. 7, the integrated circuit 80 has a rectangular shape in the plan view of the module laminate 90 but is not limited to this shape.

The integrated circuit 80 can be configured using complementary metal oxide semiconductor (CMOS), for example, and manufactured using the silicon on insulator (SOI) process according to an exemplary aspect. Note that the integrated circuit 80 is not limited to CMOS.

According to an exemplary aspect, each of the capacitors C10 to C16, C20, C30, C40, C51, C52, C61, and C71 is mounted as a chip capacitor. A chip capacitor refers to a surface mount device (SMD) that forms a capacitor. However, it is noted that multiple capacitors to be mounted are not limited to chip capacitors. For example, some or all of the multiple capacitors can be included in an integrated passive device (IPD) or in the integrated circuit 80 in alternative aspects.

According to an exemplary aspect, each of the inductors L51 to L53 is mounted as a chip inductor. A chip inductor refers to an SMD that constitutes an inductor. However, it is noted that multiple inductors to be mounted are not limited to chip inductors. For example, the multiple inductors can be included in an IPD in alternative aspects.

According to an exemplary aspect, the resistor R51 is mounted as a chip resistor. A chip resistor refers to an SMD that constitutes a resistor. However, it is noted that the resistor R51 to be mounted is not limited to a chip resistor. For example, the resistor R51 can be included in an IPD in an alternative aspect.

The multiple capacitors, multiple inductors, and multiple resistors arranged on the main surface 90a in this manner are grouped by circuit and are arranged around the integrated circuit 80.

In an exemplary aspect, the capacitor C61 included in the pre-regulator circuit 10 is arranged in a region on the main surface 90a sandwiched between a straight line along the left side of the integrated circuit 80 and a straight line along the left side of the module laminate 90 in the plan view of the module laminate 90. As a result, the group of circuit components included in the pre-regulator circuit 10 is arranged near the PR switch portion 80a in the integrated circuit 80.

A group formed by the capacitors C10 to C16, C20, C30, and C40 included in the switched-capacitor circuit 20 is arranged in a region on the main surface 90a sandwiched between a straight line along the top side of the integrated circuit 80 and a straight line along the top side of the module laminate 90 and a region on the main surface 90a sandwiched between a straight line along the right side of the integrated circuit 80 and a straight line along the right side of the module laminate 90 in the plan view of the module laminate 90. As a result, the group of circuit components included in the switched-capacitor circuit 20 is arranged near the SC switch portion 80b in the integrated circuit 80. That is, the SC switch portion 80b is arranged closer to the switched-capacitor circuit 20 than each of the PR switch portion 80a and the SM switch portion 80c is.

A group formed by the capacitors C51 and C52, inductors L51 to L53, and resistor R51 included in the filter circuit 40 is arranged in a region on the main surface 90a sandwiched between a straight line along the bottom side of the integrated circuit 80 and a straight line along the bottom side of the module laminate 90 in the plan view of the module laminate 90. As a result, the group of circuit components included in the filter circuit 40 is arranged near the SM switch portion 80c in the integrated circuit 80. That is, the SM switch portion 80c is arranged closer to the filter circuit 40 than each of the PR switch portion 80a and the SC switch portion 80b is.

At least part of the filter circuit 40 is arranged adjacent to the same side, from among the four sides, of the integrated circuit 80 (the bottom side in FIG. 7). In an exemplary aspect, at least one (the capacitor C51 and the inductors L51 and L53 in FIG. 7) of the circuit components included in the filter circuit 40 is arranged adjacent to the bottom side of the integrated circuit 80.

The capacitor C71 included in the APT switch circuit 70 is arranged adjacent to the integrated circuit 80 and is connected to the integrated circuit 80 with the wiring line 90d interposed therebetween. The capacitor C71 is arranged adjacent to the inductor L53 included in the filter circuit 40. Furthermore, at least part of the capacitor C71 overlaps at least part of the land electrode 150 that is configured to function as the output terminal 141, in the plan view of the module laminate 90. The capacitor C71 is connected to the land electrode 150 that is configured to function as the output terminal 141, with the via conductor 90c interposed therebetween.

Multiple land electrodes 150 are arranged on the main surface 90b. The multiple land electrodes 150 function as multiple external connection terminals including a ground terminal in addition to the input terminal 110 illustrated in FIG. 2, the inductor connection terminals 115 and 116, the output terminal 141, and the control terminals 601 to 604. The multiple land electrodes 150 are electrically connected to multiple electronic components arranged on the main surface 90a through via conductors formed within the module laminate 90. As the multiple land electrodes 150, copper electrodes can be used, but are not so limited. For example, as the multiple land electrodes, solder electrodes can be used. Moreover, instead of the multiple land electrodes 150, multiple bump electrodes or multiple post electrodes can be used as multiple external connection terminals.

The resin member 91 covers the main surface 90a and at least some of the multiple electronic components on the main surface 90a. The resin member 91 has the function of ensuring the reliability, such as mechanical strength and moisture resistance, of the multiple electronic components on the main surface 90a. It is also noted that the resin member 91 is not included in the tracker module 100 in some exemplary aspects.

According to an exemplary aspect, the shield electrode layer 92 is an example of a metal layer and is a thin metal film formed by sputtering, for example. The shield electrode layer 92 is formed to cover the surface (top and sides) of the resin member 91. The shield electrode layer 92 is connected to ground, which helps prevent external noise from entering the electronic components that form the tracker module 100 and also prevent noise generated by the tracker module 100 from interfering with other modules or devices. Note that the shield electrode layer 92 is not included in the tracker module 100 according to some exemplary aspects.

It is noted that the configuration of the tracker module 100 illustrated in FIGS. 7 to 9 is an example and is not so limited. For example, some of the capacitors and inductors arranged on the main surface 90a can be formed within the module laminate 90. Moreover, some of the capacitors and inductors arranged on the main surface 90a are not included in the tracker module 100 or are not arranged in or on the module laminate 90 according to some exemplary aspects.

### 1.5 Effects

As described above, the tracker circuit 1 according to the present exemplary embodiment includes the first switch circuit (for example, the pre-regulator circuit 10 and the switched-capacitor circuit 20) configured to generate multiple discrete voltages on the basis of an input voltage, the second switch circuit (for example, the power modulation circuit 30) configured to select at least one voltage from the generated multiple discrete voltages and output the at least one voltage to the power amplifier 2, the filter circuit 40 connected between the second switch circuit and the power amplifier 2, and the third switch circuit (for example, the APT switch circuit 70) that includes the capacitor C71 and switch S81 connected in series between ground and the voltage supply path P1 between the filter circuit 40 and the power amplifier 2.

According to this configuration, the switch S81 can switch between connection and disconnection of the voltage supply path P1 to and from ground with the capacitor C71 interposed therebetween. Thus, the bypass capacitor can be switched between on and off in accordance with the characteristics of the power supply voltage supplied to the power amplifier 2 via the voltage supply path P1. For example, when voltage is supplied in the APT mode, by connecting the voltage supply path P1 to ground with the capacitor C71 interposed therebetween, improving the stability of the power supply voltage V_{APT} and improving the quality of the transmission signal can be achieved. For example, when voltage is supplied in the digital ET mode, by disconnecting the voltage supply path P1 from ground with the capacitor C71 interposed therebetween, suppressing a decrease in the tracking performance of the power supply voltage V_{ET} and improving PAE can be achieved. Furthermore, according to this, the third switch circuit is connected between the filter circuit 40 and the power amplifier 2. Thus, the effect of the filter circuit 40 on the impedance of the power amplifier 2 can be reduced, so that the design of the filter circuit 40 can be made easier, and the degradation of the characteristics of the power amplifier 2 due to the filter circuit 40 is suppressed. According to this configuration, the third switch circuit is included in the tracker circuit 1. Thus, it is easy to synchronize the on/off switching timing of the switch S81 with the tracking mode switching timing, and suppressing a decrease in the stability or tracking performance of the power supply voltage due to the delay in the control of the switch S81 can be achieved.

For example, in the tracker circuit 1 according to the present exemplary embodiment, the switch S81 can be connected between the capacitor C71 and ground.

According to this configuration, the one end of the switch S81 is connected to ground. Thus, it is easier to integrate the switch S81 with other switches, for example, thereby contributing to the downsizing of the tracker circuit 1.

For example, in the tracker circuit 1 according to the present exemplary embodiment, in a situation where at least one voltage is selected on the basis of the APT mode, the switch S81 of the third switch circuit can connect the voltage supply path P1 to ground with the capacitor C71 interposed therebetween, and in a situation where at least one voltage is selected on the basis of the digital ET mode, the switch S81 of the third switch circuit does not connect the voltage supply path P1 to ground with the capacitor C71 interposed therebetween according to an exemplary aspect of the present disclosure.

According to this configuration, when voltage is supplied in the APT mode, by connecting the voltage supply path P1 to ground with the capacitor C71 interposed therebetween, improving the stability of the power supply voltage V_{APT} and improving the quality of the transmission signal can be achieved. In contrast, in a case where voltage is supplied in the digital ET mode, by disconnecting the voltage supply path P1 from ground with the capacitor C71 interposed therebetween, suppressing a decrease in the tracking performance of the power supply voltage V_{ET} and improving PAE can be achieved.

For example, in the tracker circuit 1 according to the present exemplary embodiment, the filter circuit 40 can include the inductors L51 to L53 and the capacitors C51 and C52, and the capacitance of the capacitor C71 of the third switch circuit can be larger than the capacitance of the capacitor C51 or C52 of the filter circuit.

According to this configuration, the capacitor C71 having a relatively large capacitance can be connected between the voltage supply path P1 and ground, thereby further improving the stability of the power supply voltage.

The tracker module 100 according to the present exemplary embodiment includes the module laminate 90 having the main surfaces 90a and 90b that face each other, the output terminal 141 provided in or on the module laminate 90, the first switch circuit (for example, the pre-regulator circuit 10 and the switched-capacitor circuit 20) that is arranged in or on the module laminate 90 and is configured to generate multiple discrete voltages on the basis of the input voltage, the second switch circuit (for example, the power modulation circuit 30) that is arranged in or on the module laminate 90 and is configured to select at least one voltage from the generated multiple discrete voltages and output the at least one voltage to the power amplifier 2 via the output terminal 141, the filter circuit 40 that is arranged in or on the module laminate 90 and is connected between the second switch circuit and the output terminal 141, and the third switch circuit (for example, the APT switch circuit 70) that is arranged in or on the module laminate 90 and includes the capacitor C71 and the switch S81 connected in series, and the third switch circuit is connected between ground and the voltage supply path P1 between the filter circuit 40 and the output terminal 141.

According to this configuration, the switch S81 can switch between connection and disconnection of the voltage supply path P1 to and from ground with the capacitor C71 interposed therebetween. Thus, the bypass capacitor can be switched between on and off in accordance with the characteristics of the power supply voltage supplied to the power amplifier 2 via the voltage supply path P1. For example, when voltage is supplied in the APT mode, by connecting the voltage supply path P1 to ground with the capacitor C71 interposed therebetween, improving the stability of the power supply voltage V_{APT} and improving the quality of the transmission signal can be achieved. For example, in a case where voltage is supplied in the digital ET mode, by disconnecting the voltage supply path P1 from ground with the capacitor C71 interposed therebetween, suppressing a decrease in the tracking performance of the power supply voltage V_{ET} and improving PAE can be achieved. Furthermore, according to this, the third switch circuit is connected between the filter circuit 40 and the power amplifier 2. Thus, the effect of the filter circuit 40 on the impedance of the power amplifier 2 can be reduced, so that the design of the filter circuit 40 can be made easier, and the degradation of the characteristics of the power amplifier 2 due to the filter circuit 40 is suppressed. According to this configuration, the third switch circuit is included in the tracker module 100. Thus, it is easy to synchronize the on/off switching timing of the switch S81 with the tracking mode switching timing, and suppressing a decrease in the stability or tracking performance of the power supply voltage due to the delay in the control of the switch S81 can be achieved.

Moreover, for example, in the tracker module 100 according to the present exemplary embodiment, the switch S81 can be connected between the capacitor C71 and ground.

According to this configuration, the one end of the switch S81 is connected to ground. Thus, it is easier to integrate the switch S81 with other switches, for example, thereby contributing to the downsizing of the tracker module 100.

For example, in the tracker module 100 according to the present exemplary embodiment, in a situation where at least one voltage is selected on the basis of the APT mode, the switch S81 of the third switch circuit can connect the voltage supply path P1 to ground with the capacitor C71 interposed therebetween, and in a situation where at least one voltage is selected on the basis of the digital ET mode, the switch S81 of the third switch circuit does not connect the voltage supply path P1 to ground with the capacitor C71 interposed therebetween in an exemplary example.

According to this configuration, when voltage is supplied in the APT mode, by connecting the voltage supply path P1 to ground with the capacitor C71 interposed therebetween, improving the stability of the power supply voltage V_{APT} and improving the quality of the transmission signal can be achieved. In contrast, in a case where voltage is supplied in the digital ET mode, by disconnecting the voltage supply path P1 from ground with the capacitor C71 interposed therebetween, suppressing a decrease in the tracking performance of the power supply voltage V_{ET} and improving PAE can be achieved.

For example, in the tracker module 100 according to the present exemplary embodiment, the filter circuit 40 can include the inductors L51 to L53 and the capacitors C51 and C52, and the capacitance of the capacitor C71 of the third switch circuit can be larger than the capacitance of the capacitor C51 or C52 of the filter circuit 40.

According to this configuration, the capacitor C71 having a relatively large capacitance can be connected between the voltage supply path P1 and ground, thereby further improving the stability of the power supply voltage.

For example, in the tracker module 100 according to the present exemplary embodiment, the second switch circuit can include the switches S51 to S54, and the switches S51 to S54 of the second switch circuit and the switch S81 of the third switch circuit can be included in the integrated circuit 80, which is a single integrated circuit.

According to this configuration, the switches S51 to S54 of the second switch circuit and the switch S81 of the third switch circuit are integrated into the integrated circuit 80, which is a single integrated circuit, thereby contributing to the downsizing of the tracker module 100.

For example, in the tracker module 100 according to the present exemplary embodiment, the integrated circuit 80 can be arranged on the main surface 90a, and the capacitor C71 of the third switch circuit can be arranged on the main surface 90a and adjacent to the integrated circuit 80.

According to this configuration, the capacitor C71 is arranged adjacent to the integrated circuit 80 including the switch S81. Thus, the wiring line 90d connecting the capacitor C71 to the switch S81 is shortened, thereby reducing the impedance, particularly inductance, of the wiring line 90d can be achieved. As a result, the characteristic degradation of the capacitor C71 due to the increased impedance of the wiring line 90d is suppressed, and the stability of the power supply voltage due to the capacitor C71 can be further improved.

For example, in the tracker module 100 according to the present exemplary embodiment, the filter circuit 40 can include the inductors L51 to L53 and capacitors C51 and C52 arranged on the main surface 90a, and the capacitor C71 of the third switch circuit can be arranged on the main surface 90a and adjacent to the inductor L53 of the filter circuit 40.

According to this configuration, the capacitor C71 is arranged adjacent to the inductor L53 of the filter circuit 40. Thus, the wiring line connecting the capacitor C71 to the inductor L53 is shortened, thereby reducing the impedance, particularly inductance, of the wiring line can be achieved. As a result, the characteristic degradation of the capacitor C71 due to the increased impedance of the wiring line is suppressed, and the stability of the power supply voltage due to the capacitor C71 can be further improved.

For example, in the tracker module 100 according to the present exemplary embodiment, the output terminal 141 can be arranged on the main surface 90b, and at least part of the capacitor C71 of the third switch circuit can overlap at least part of the output terminal 141 in the plan view of the module laminate 90.

According to this configuration, the wiring length between the capacitor C71 and the output terminal 141 arranged on the main surfaces 90a and 90b, which face each other, of the module laminate 90, respectively, is shortened. Thus, the impedance, particularly inductance, of the wiring line can be reduced, the characteristic degradation of the capacitor C71 due to the increased impedance of the wiring line is suppressed, and the stability of the power supply voltage due to the capacitor C71 can be further improved.

The voltage supply method according to the present exemplary embodiment includes generating multiple discrete voltages on the basis of the input voltage (S101), selecting at least one voltage from the generated multiple discrete voltages (S103), filtering the selected at least one voltage (S105), switching between connection and disconnection of the voltage supply path P1, which is for supplying the at least one voltage after the filtering to the power amplifier 2, to and from ground with the capacitor C71 interposed therebetween (S107), and supplying the at least one voltage after the filtering to the power amplifier 2 via the voltage supply path P1 (S109).

This can switch between connection and disconnection of the voltage supply path P1, which is for supplying the at least one voltage after the filtering to the power amplifier 2, to and from ground with the capacitor C71 interposed therebetween. Thus, the bypass capacitor is configured to be switched between on and off in accordance with the characteristics of the power supply voltage supplied to the power amplifier 2 via the voltage supply path P1. For example, in a case where voltage is supplied in the APT mode, by connecting the voltage supply path P1 to ground with the capacitor C71 interposed therebetween, improving the stability of the power supply voltage V_{APT} and improving the quality of the transmission signal can be achieved. For example, in a case where voltage is supplied in the digital ET mode, by disconnecting the voltage supply path P1 from ground with the capacitor C71 interposed therebetween, suppressing a decrease in the tracking performance of the power supply voltage V_{ET} and improving PAE can be achieved.

For example, in the power voltage supply method according to the present exemplary embodiment, when switching between connection and disconnection of the voltage supply path to and from ground with the capacitor interposed therebetween (S107), when at least one voltage is selected on the basis of the APT mode (APT in S1071), electrical conduction can be allowed through the switch S81 connected in series with the capacitor C71 between the voltage supply path P1 and ground (S1072), and when at least one voltage is selected on the basis of the digital ET mode (D-ET in S1071), electrical conduction does not have to be allowed through the switch S81 (S1073) in an exemplary aspect.

According to this, the switch S81 can switch between connection and disconnection of the voltage supply path P1, which is for supplying at least one voltage after the filtering to the power amplifier 2, to and from ground with the capacitor C71 interposed therebetween.

### Modification

The following is a description of a modification of the above-described exemplary embodiments. In the present modification, an APT switch circuit is mainly different from the above-described exemplary embodiments in that the capacitor can be discharged. In the following, the APT switch circuit according to the present modification will be described with reference to the drawing.

FIG. 10 is a circuit configuration diagram of an APT switch circuit 70A according to the present modification. As illustrated in FIG. 10, the APT switch circuit 70A according to the present modification is an example of the third switch circuit and includes a switch S82 in addition to the capacitor C71 and the switch S81.

The switch S82 is connected in parallel with the capacitor C71 between the path P1 and the switch S81. In an exemplary aspect, the switch S82 includes a terminal connected to the one end of the capacitor C71 and a terminal connected to the other end of the capacitor C71. In this connection configuration, the switch S82 is configured to be switched between on and off by the control signal S4 to switch between connection and disconnection of the one end and the other end of the capacitor C71. For example, by turning on the switch S82 when the switch S81 is off, the capacitor C71 is discharged.

It is noted that the on and off of the switch S82 does not switch instantaneously in an exemplary aspect. For example, the switch S82 can be turned on gradually. This configuration suppresses changes in the power supply voltage caused by turning on the switch S82.

### Additional Exemplary Embodiments

The tracker circuit, the tracker module, and the voltage supply method according to the present disclosure have been described above on the basis of the exemplary embodiments. However, it is noted that the tracker circuits, tracker modules, and voltage supply methods according to the present disclosure are not limited to the exemplary embodiments described above. The present disclosure also includes other exemplary embodiments realized by combining any of the constituent elements in the above exemplary embodiments, modifications obtained by adding, to the above exemplary embodiments various, changes that those skilled in the art can conceive of without departing from the gist of the present disclosure, and various devices in which the above tracker circuit is built.

For example, in the circuit configurations of various circuits according to the above exemplary embodiments, another circuit element and another wiring line, for example, can be inserted between individual circuit elements and the paths connecting signal paths disclosed in the drawings. For example, an impedance matching circuit can be inserted between the power amplifier 2 and the filter 3.

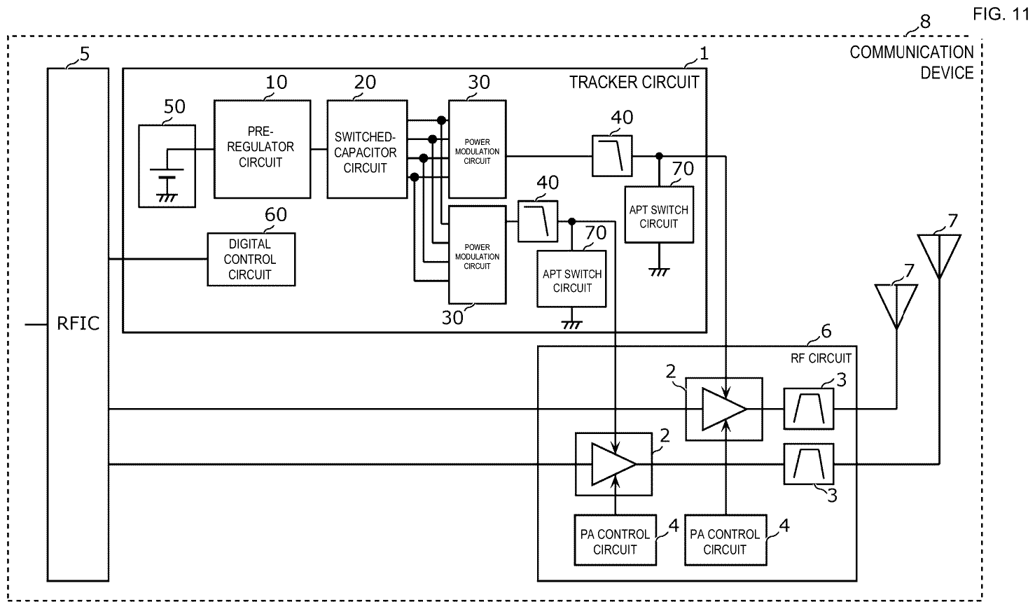

Note that in the above exemplary embodiments, the tracker circuit is configured to supply voltage to one power amplifier but can supply voltage to multiple power amplifiers. In this case, the multiple power amplifiers can be supplied with the same voltage or different voltages. For example, as illustrated in FIG. 11, in a case where different voltages are supplied to two power amplifiers, the tracker circuit 1 can include the pre-regulator circuit 10, the switched-capacitor circuit 20, two power modulation circuits 30, which are connected to the switched-capacitor circuit 20, two filter circuits 40, which are connected to the two respective power modulation circuits 30, and two APT switch circuits 70, which are connected to the two respective filter circuits 40. According to this, the two power amplifiers 2 can share the pre-regulator circuit 10 and the switched-capacitor circuit 20, and thus an increase in the number of components is minimized.

Note that in the above exemplary embodiments, multiple discrete voltages are supplied from the switched-capacitor circuit to the power modulation circuit or circuits, but this is not the only possible case. For example, multiple voltages can be supplied from multiple respective DC-DC converters. Note that in a case where the voltage levels of the multiple discrete voltages are equally spaced, a switched-capacitor circuit is used in some exemplary examples, which is effective in downsizing the tracker module.

Note that four discrete voltages are supplied in the above exemplary embodiments, but the number of discrete voltages is not limited to four. For example, PAE can be improved in a case where multiple discrete voltages include at least the voltage corresponding to the maximum output power and the voltage corresponding to the output power that occurs most frequently.

Note that in the above exemplary embodiments, the multiple circuit components of the tracker circuit 1 are arranged on the main surface 90a of the module laminate but can be arranged on both the main surfaces 90a and 90b. In this case, for example, the integrated circuit 80 can be arranged on the main surface 90b.

Note that in the above-described exemplary embodiments, the control of the APT switch circuit 70 has been described using the two tracking modes, the APT mode and the digital ET mode, as examples, but the tracking modes that the tracker circuit 1 can support are not limited to the APT mode and the digital ET mode. For example, the tracker circuit 1 can support the SPT mode and the digital ET mode. In this case, the APT switch circuit 70 can allow electrical conduction through the switch S81 (that is, turned on) in the SPT mode and can stop electrical conduction through the switch S81 (that is, turned off) in the digital ET mode. This can improve the stability of the power supply voltage in the SPT mode and suppress a decrease in the tracking performance of the power supply voltage in the digital ET mode. For example, the tracker circuit 1 can support the APT mode and the SPT mode. In this case, the APT switch circuit 70 can allow electrical conduction through the switch S81 in the APT mode and can stop electrical conduction through the switch S81 in the SPT mode. This can improve the stability of the power supply voltage in the APT mode and suppress a decrease in the tracking performance of the power supply voltage in the SPT mode.

The following are features of the tracker circuit, tracker module, and voltage supply method described on the basis of the above exemplary embodiments.

<1> A tracker circuit including a first switch circuit configured to generate a plurality of discrete voltages, based on an input voltage, a second switch circuit configured to select at least one voltage from the plurality of generated discrete voltages and output the at least one voltage to an amplifier, a filter circuit connected between the second switch circuit and the amplifier, and a third switch circuit including a capacitor and a switch that are connected in series between ground and a voltage supply path between the filter circuit and the amplifier.

<2> The tracker circuit according to <1>, in which in the third switch circuit, the switch is connected between the capacitor and ground.

<3> The tracker circuit according to <1> or <2>, in which in a situation where the at least one voltage is selected based on an average power tracking mode or a symbol power tracking mode, the switch of the third switch circuit connects the voltage supply path to ground with the capacitor interposed therebetween, and in a situation where the at least one voltage is selected based on a digital envelope tracking mode, the switch of the third switch circuit does not connect the voltage supply path to ground with the capacitor interposed therebetween.

<4> The tracker circuit according to any one of <1> to <3>, in which the filter circuit includes an inductor and a capacitor, and a capacitance of the capacitor of the third switch circuit is larger than a capacitance of the capacitor of the filter circuit.

<5> A tracker module including a module laminate having a first main surface and a second main surface that face each other, an external connection terminal provided in or on the module laminate, a first switch circuit that is arranged in or on the module laminate and is configured to generate, based on an input voltage, a plurality of discrete voltages, a second switch circuit that is arranged in or on the module laminate and is configured to select at least one voltage from the plurality of generated discrete voltages and output the at least one voltage to an amplifier via the external connection terminal, a filter circuit that is arranged in or on the module laminate and is connected between the second switch circuit and the external connection terminal, and a third switch circuit that is arranged in or on the module laminate and includes a capacitor and a switch that are connected in series, and the third switch circuit is connected between ground and a voltage supply path between the filter circuit and the external connection terminal.

<6> The tracker module according to <5>, in which in the third switch circuit, the switch is connected between the capacitor and ground.

<7> The tracker module according to <5> or <6>, in which in a situation where the at least one voltage is selected based on an average power tracking mode or a symbol power tracking mode, the switch of the third switch circuit connects the voltage supply path to ground with the capacitor interposed therebetween, and in a situation where the at least one voltage is selected based on a digital envelope tracking mode, the switch of the third switch circuit does not connect the voltage supply path to ground with the capacitor interposed therebetween.

<8> The tracker module according to any one of <5> to <7>, in which the filter circuit includes an inductor and a capacitor, and a capacitance of the capacitor of the third switch circuit is larger than a capacitance of the capacitor of the filter circuit.

<9> The tracker module according to any one of <5> to <8>, in which the second switch circuit includes a switch, and the switch of the second switch circuit and the switch of the third switch circuit are included in a single integrated circuit.

<10> The tracker module according to <9>, in which the integrated circuit is arranged on the first main surface, and the capacitor of the third switch circuit is arranged on the first main surface and adjacent to the integrated circuit.

<11> The tracker module according to any one of <5> to <10>, in which the filter circuit includes an inductor and a capacitor arranged on the first main surface, and the capacitor of the third switch circuit is arranged on the first main surface and adjacent to at least one of the inductor and the capacitor of the filter circuit.

<12> The tracker module according to any one of <5> to <11>, in which the external connection terminal is arranged on the second main surface, and at least part of the capacitor of the third switch circuit overlaps at least part of the external connection terminal in a plan view of the module laminate.

<13> A voltage supply method including generating a plurality of discrete voltages, based on an input voltage, selecting at least one voltage from the plurality of generated discrete voltages, filtering the selected at least one voltage, switching between grounding and not grounding a noise component included in the at least one voltage after the filtering, and supplying the at least one voltage after the filtering to an amplifier via a voltage supply path.

<14> The voltage supply method according to <13>, in which in the switching between connection and disconnection of the voltage supply path to and from ground with the capacitor interposed therebetween, in a case where the at least one voltage is selected based on an average power tracking mode or a symbol power tracking mode, electrical conduction is allowed through a switch connected in series with the capacitor between the voltage supply path and ground, and in a case where the at least one voltage is selected based on a digital envelope tracking mode, electrical conduction is not allowed through the switch.

The present disclosure can be widely used in communication devices, such as mobile phones, as a tracker circuit that supplies voltage to a power amplifier.

### REFERENCE SIGNS LIST

1 tracker circuit
2 power amplifier
3 filter
4 PA control circuit
5 RFIC
6 radio frequency circuit
7 antenna
8 communication device
10 pre-regulator circuit
20 switched-capacitor circuit
30 power modulation circuit
40 filter circuit
50 direct current power source
60 digital control circuit
61 first controller
62 second controller
70, 70A APT switch circuit
80 integrated circuit
80a PR switch portion
80b SC switch portion
80c SM switch portion
80d APT switch portion
90 module laminate
90a, 90b main surface
90c via conductor
90d wiring line
90e ground plane
91 resin member
92 shield electrode layer
100 tracker module
110, 131, 132, 133, 134, 140 input terminal
111, 130, 141 output terminal
115, 116 inductor connection terminal
150 land electrode
601, 602, 603, 604 control terminal
C10, C11, C12, C13, C14, C15, C16, C20, C30, C40, C51, C52, C61, C71 capacitor
L51, L52, L53 inductor
L71 power inductor
N1, N2, N3, N4 node
P1 voltage supply path
R51 resistor
S1, S2, S3, S4 control signal
S11, S12, S13, S14, S21, S22, S23, S24, S31, S32, S33, S34, S41, S42, S43, S44, S51, S52, S53, S54, S61, S62, S71, S72, S81 switch
V1, V2, V3, V4 voltage
V_{ET}, V_{APT} power supply voltage

What is claimed is:

1. A tracker circuit comprising:
a first switch circuit configured to generate a plurality of discrete voltages based on an input voltage;
a second switch circuit configured to select at least a first voltage from the plurality of discrete voltages as a supply voltage;
a filter circuit that is connected to the second switch circuit and is configured to filter the supply voltage and generate a filtered supply voltage that is provided to an amplifier via a voltage supply path between the filter circuit and the amplifier; and
a third switch circuit including a first capacitor and a first switch that are connected in series between a ground and the voltage supply path.

2. The tracker circuit according to claim 1, wherein, in the third switch circuit, the first switch is connected between the first capacitor and the ground.

3. The tracker circuit according to claim 1, wherein:
when the tracker circuit is configured in an average power tracking mode or a symbol power tracking mode for selecting the at least first voltage, the first switch of the third switch circuit is configured to connect the voltage supply path to the ground with the first capacitor interposed therebetween, and
when the tracker circuit is configured in a digital envelope tracking mode for selecting the at least first voltage, the first switch of the third switch circuit is configured to not connect the voltage supply path from the ground.

4. The tracker circuit according to claim 1, wherein:
the filter circuit includes an inductor and a second capacitor, and
a first capacitance of the first capacitor of the third switch circuit is larger than a second capacitance of the second capacitor of the filter circuit.

5. The tracker circuit according to claim 1, wherein the third switch circuit includes a second switch that is connected with the first capacitor in parallel.

6. The tracker circuit according to claim 5, wherein the second switch is switched on when the first switch is switched off.

7. A tracker module comprising:
a module laminate having a first main surface and a second main surface that oppose each other;
an external connection terminal in or on the module laminate;
a first switch circuit that is arranged in or on the module laminate and is configured to generate, based on an input voltage, a plurality of discrete voltages;
a second switch circuit that is arranged in or on the module laminate and is configured to select at least a first voltage from the plurality of discrete voltages as a supply voltage;
a filter circuit that is arranged in or on the module laminate, is connected to the second switch circuit, and is configured to filter the supply voltage and generate a filtered supply voltage that is provided to the external connection terminal via a voltage supply path; and
a third switch circuit that is arranged in or on the module laminate and includes a first capacitor and a first switch that are connected in series between a ground and the voltage supply path.

8. The tracker module according to claim 7, wherein, in the third switch circuit, the first switch is connected between the first capacitor and the ground.

9. The tracker module according to claim 7, wherein:
when the tracker module is configured in an average power tracking mode or a symbol power tracking mode for selecting the at least first voltage, the first switch of the third switch circuit is configured to connect the voltage supply path to the ground with the first capacitor interposed therebetween, and
when the tracker module is configured in a digital envelope tracking mode for selecting the at least first voltage, the first switch of the third switch circuit is configured to not connect the voltage supply path from the ground.

10. The tracker module according to claim 7, wherein:
the filter circuit includes an inductor and a second capacitor, and
a first capacitance of the first capacitor of the third switch circuit is larger than a second capacitance of the second capacitor of the filter circuit.

11. The tracker module according to claim 7, wherein:
the second switch circuit includes one or more second switches, and
the one or more second switches of the second switch circuit and the first switch of the third switch circuit are included in a single integrated circuit.

12. The tracker module according to claim 11, wherein:
the single integrated circuit is arranged on the first main surface, and
the first capacitor of the third switch circuit is arranged on the first main surface and adjacent to the single integrated circuit.

13. The tracker module according to claim 7, wherein:
the filter circuit includes an inductor and a second capacitor arranged on the first main surface, and
the first capacitor of the third switch circuit is arranged on the first main surface and adjacent to at least one of the inductor and the second capacitor of the filter circuit.

14. The tracker module according to claim 7, wherein:
the external connection terminal is arranged on the second main surface, and
at least a part of the first capacitor of the third switch circuit overlaps at least a part of the external connection terminal in a plan view of the module laminate.

15. The tracker module according to claim 7, wherein the third switch circuit includes a second switch that is connected with the first capacitor in parallel.

16. The tracker module according to claim 15, wherein the second switch is switched on when the first switch is switched off.

17. A voltage supply method comprising:
generating a plurality of discrete voltages based on an input voltage;
selecting at least a first voltage from the plurality of discrete voltages as a voltage supply;
filtering the voltage supply to generate a filtered voltage supply;
switching between a connection and a disconnection of a voltage supply path to and from a ground with a capacitor interposed therebetween; and
supplying the filtered voltage supply via the voltage supply path to an amplifier.

18. The voltage supply method according to claim 17, wherein the switching between the connection and the disconnection comprises:
when the voltage supply is selected based on an average power tracking mode or a symbol power tracking mode, switching on a first switch that is connected in series with the capacitor between the voltage supply path and the ground; and
when the voltage supply is selected based on a digital envelope tracking mode, switching off the first switch.

19. The voltage supply method according to claim 18, further comprising switching on a second switch that is connected with the capacitor in parallel when the first switch is switched off.
